(19) United States
(12) Patent Application Publication
(10) Pub. No.: US 2012/0224314 A1
(43) Pub. Date: Sep. 6, 2012

(54) Method and System for Keyboard Tray and Portable Computer Projector Display

(76) Inventors: Chris Hinshaw, Redmond, WA (US); Karl Mills, Lynnwood, WA (US)

(21) Appl. No.: 13/039,251

(22) Filed: Mar. 2, 2011

(51) Int. Cl. H05K 7/00

(52) U.S. Cl. 361/679.09; 361/679.01

(57) ABSTRACT

Keyboard trays, laptops and portable computers are provided having a display comprised of a small projector that projects onto a screen instead of a standard LCD or flat panel display that generates images itself. They provide a keyboard tray or portable computer in which a laser, high brightness LED, LCD, LCoS, or other suitable projector module is embedded within the keyboard or base portion of the keyboard tray or portable computer, and the display comprises a reflective projector screen made of plastic or other suitable material protected by a thin cover made of plastic or other suitable material. They provide a keyboard tray or portable computer display that is thinner, more durable and more easily and economically repaired than typical LCD and other flat panel displays.

This generally relates to keyboard trays and portable computers and more particularly to a display unit utilizing image projection technology for such devices.

### BACKGROUND

The use of computers has vastly increased over the past two decades, to the point where computers are an integral part of many people's work and home life. One of the major uses of the computer is viewing content, from professional presentations and academic papers to video games, movies, and television shows. This use has created consumer demand for ever improving display systems within keyboard trays and portable computers, causing displays to become progressively larger and more technologically advanced.

A typical keyboard tray or portable computer includes a keyboard and a display screen. A typical portable computer also contains a processor, while a typical keyboard tray does not. The most common types of keyboard trays and portable computers contain an LCD or other flat panel display that generates images viewable by a user. These screens are often thick because they contain many electronics and are also normally protected by a hard plastic cover. These screens are normally mechanically connected to the keyboard by hinges, which must be robust due to the heft of an LCD or flat panel display caused by the weight of the internal electronics and protective cover, and are normally electronically connected to the keyboard as well through wires and/or other electronic connections.

The aforementioned characteristics of LCD's and other flat panel displays create myriad problems. First, many large common keyboard tray and portable computer displays measure 17.1 inches or more diagonally. This is large enough for personal viewing, but too small to be viewed at any appreciable distance, limiting the number of people who may view the content on the LCD or other flat panel display to a few at a time. Second, LCD and other flat panel displays are comparatively fragile due to their delicate screens and intricate internal electronics. They are easily damaged, and their repair is difficult and thus, expensive. Third, LCD and other flat panel displays are comparatively thick because they must have room to contain the requisite electronics and because practicality requires they be protected by a hard cover of some sort. Thus, keyboards must be thinner to offset the thickness of the LCD or other flat panel display and allow manufacturers to meet consumer demand for increasingly thinner portable computers.

This thickness consideration is also a major concern in keyboard trays, where the challenge is to create a keyboard tray that can slide into a server rack and thus, have a thickness less than 1.75 inches (1 “rack unit”), for example. Within computer servers designed for rack mounting with a large number of computers in the single rack, space and economic considerations often dictate that it is impractical to have a separate keyboard, mouse, and monitor associated with each computer. Instead, a keyboard tray connected to a KVM switch for routing signals from the keyboard tray to the appropriate computer is often used to share the single keyboard tray among the many different computers. In such a configuration, a user may control any of the computers connected to the outputs of the KVM switch after configuring the KVM switch to route the signals from the keyboard tray to the appropriate target computer. The thinner, lower profile keyboards required because of the thickness of typical LCD or other flat panel display are more expensive than standard keyboard technology, again raising the price of a typical keyboard tray or portable computer.

Accordingly, there is a desire for a keyboard tray or portable computer display that is large enough to allow content to be seen by many viewers concurrently. There is also a desire for a keyboard tray or portable computer display that is more durable and more easily and economically repaired than typical LCD and other flat panel displays. There is a further desire for a keyboard tray or portable computer display that is thinner than typical LCD and other flat panel displays.

### SUMMARY

In accordance with the methods and systems consistent with the present invention, a KVM keyboard tray is provided comprising a keyboard. The KVM keyboard tray further comprises a display comprising a projector configured to project an image onto a screen, and the screen configured to receive the projected image from the projector.

In one implementation, a portable computer is provided comprising a keyboard and a processor. The portable computer also comprises a display comprising a projector configured to project an image onto a screen, and the screen configured to receive the projected image from the projector.

### BRIEF DESCRIPTION OF THE DRAWINGS

FIG. 1 depicts a keyboard tray with hinged, flip down projection screen in the open position, in accordance with methods and systems consistent with the present invention.

FIG. 2 depicts a block diagram of a keyboard tray and its electronic connections to a plurality of servers through a keyboard, video, mouse (KVM) switch and a plurality of KVM Rack Interface Pod (KVM RIP) devices, in accordance with the methods and systems consistent with the present invention.

FIG. 3 depicts a block diagram of a keyboard tray and its electronic connections to a server, in accordance with the methods and systems consistent with the present invention.

FIG. 4 illustrates an exemplary target computer system consistent with methods and systems consistent with the present invention.

### DETAILED DESCRIPTION

Methods and systems in accordance with the present invention provide a keyboard tray, laptop or other portable computer having a display comprised of a small projector that projects onto a screen instead of a standard LCD or flat panel display that generates images itself. They provide a keyboard tray or portable computer in which a laser, high brightness LED, LCD, LCoS, or other suitable projector module is embedded within the keyboard or base portion of the keyboard tray or portable computer, and the display comprises a reflective projector screen made of plastic or other suitable material protected by a thin cover made of plastic or other suitable material.

Methods and systems consistent with the present invention may provide a keyboard tray or portable computer display that is large enough to allow content to be seen by many viewers concurrently. They also provide a keyboard tray or portable computer display that is more durable and more easily and economically repaired than typical LCD and other flat panel displays. They may also be thinner than typical LCD and other flat panel displays.

The display screen can be a hinged, fold-out screen, a retractable screen, a collapsible screen that folds or rolls up, or any other suitable screen. In one implementation, the display screen moves to a particular “snap-to” location so that the image is provided in proper focus. In another implementation, a specific laser or other suitable projector is provided such that the image is in focus, regardless of the position of the screen and the distance over which the image is projected. This implementation allows the user to move the screen out of the path of the projected images, either by opening the hinges to a full 180° or by not engaging the retractable or collapsible screen, and thus project the image onto a large, distant surface or non-attached projection screen such as those in many conference rooms and auditoriums. This alternate implementation could also be provided without a screen, limiting projection to remote and/or unattached screens or a wall.

Projection screen displays such as those used in conjunction with systems consistent with the present invention typically comprise sheets of plastic or other suitable material and do not contain electronics nor require electronic connection to the keyboard or base portion of the keyboard tray or portable computer, making them durable and easily replaced. Additionally, such projection screen displays may be typically thinner than typical LCD or other flat panel displays because they do not contain electronics or require thick protective coverings, thereby allowing for the use of a thicker, more cost-efficient keyboard while still allowing the manufacturer to meet consumer demands regarding thickness of the keyboard tray or portable computer. Finally, displays of various resolutions can be displayed on the single display area if the projector includes the proper optics, and the keyboard tray or portable computer can be easily updated with improving projection technology by simply swapping out the projector module embedded in the keyboard or base portion with no need to swap out the entire display screen since it is merely a blank screen made of plastic or other suitable material.

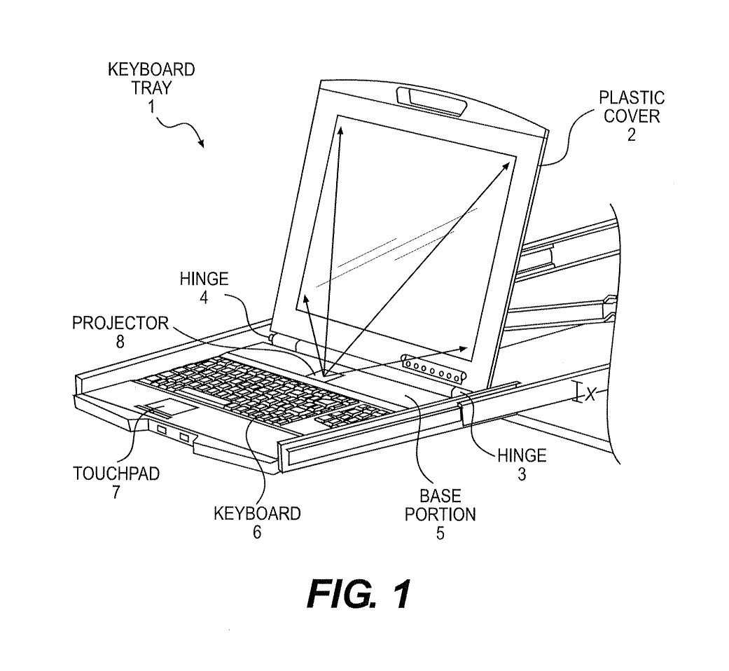

FIG. 1 illustrates an exemplary embodiment of a keyboard tray made in accordance with methods and systems consistent with the present invention. Keyboard tray 1, when closed, has a height X which is less than or equal to 1.75 inches, or 1 “rack unit,” (RU) allowing it to fit into a typical server rack when closed. In other exemplary embodiments, the height of keyboard tray 1 may be greater than 1 RU. The user opens plastic cover 2, which pivots about hinge 3 and hinge 4, exposing the base portion 5 which includes keyboard 6, touchpad 7 and projector 8. In other exemplary embodiments, protective cover 2 may be absent. Once keyboard tray 1 is powered on, projector 8 projects displayed images either onto projection screen 9, which is embedded in plastic cover 2, or onto a remote projection screen if projection screen 9 is moved out of the projected image's path by opening hinge 3 and hinge 4 to an appropriate obtuse angle. In other exemplary embodiments, projection screen 9 may not be embedded in a plastic cover at all, but may instead be a fold out, retractable, or collapsible screen or any other suitable screen. In such alternate embodiments, hinge 3 and hinge 4 may be absent.

Projector 8 may be a “pico projector.” A pico projector (a.k.a. “pocket projector,” “mobile projector,” etc.) is technology that has emerged in response to the creation of compact portable devices such as cell phones, PDAs, and digital cameras, which have sufficient storage capacity to handle presentation materials, but little space to accommodate an attached display screen. Pico projectors use miniaturized hardware and software to project digital images onto any nearby viewing surface. The entire system may be compacted into a single chip, and importantly, pico projectors are typically capable of projecting a clear image regardless of the physical characteristics of the viewing surface. One embodiment consistent with the present invention includes a laser based projector, which does not require focusing, but other projectors, including high brightness based LED projectors, LCD based projectors, LCoS based projectors, or any other suitable projector may be used provided that the embodiment may include special lensing and a method to adjust the focus, such as keystone correction or any other suitable method.

Methods and systems in accordance with the present invention may also be applicable to laptops and other portable computers as well as to keyboard trays. A typical laptop or other portable computer comprises a keyboard, a monitor or other type of display screen, a mouse, touchpad, or other pointing device, and a processor. The inclusion of a processor, which is the primary element carrying out the laptop or other portable computer's functions in response to the instructions of a computer program, allows the laptop or other portable computer to act as a standalone personal computing device. A typical keyboard tray comprises a keyboard, monitor or other type of display screen, and a mouse, touchpad, or other pointing device. A typical keyboard tray does not contain the processor inherent in a typical laptop because a keyboard tray is not intended to be operated in a stand alone fashion. Instead, keyboard trays are typically used to control one or more remote devices, usually through connection using KVM cables and KVM switches. A laptop in accordance with the present invention may appear similar to the keyboard tray in FIG. 1. The laptop may have a keyboard, processor, projector connected to the keyboard or base portion housing the keyboard, and a screen attached to the keyboard. The projector 8 may project the image on the screen, similar to as shown in FIG. 1, and the screen may reflect the projector's image to the user.

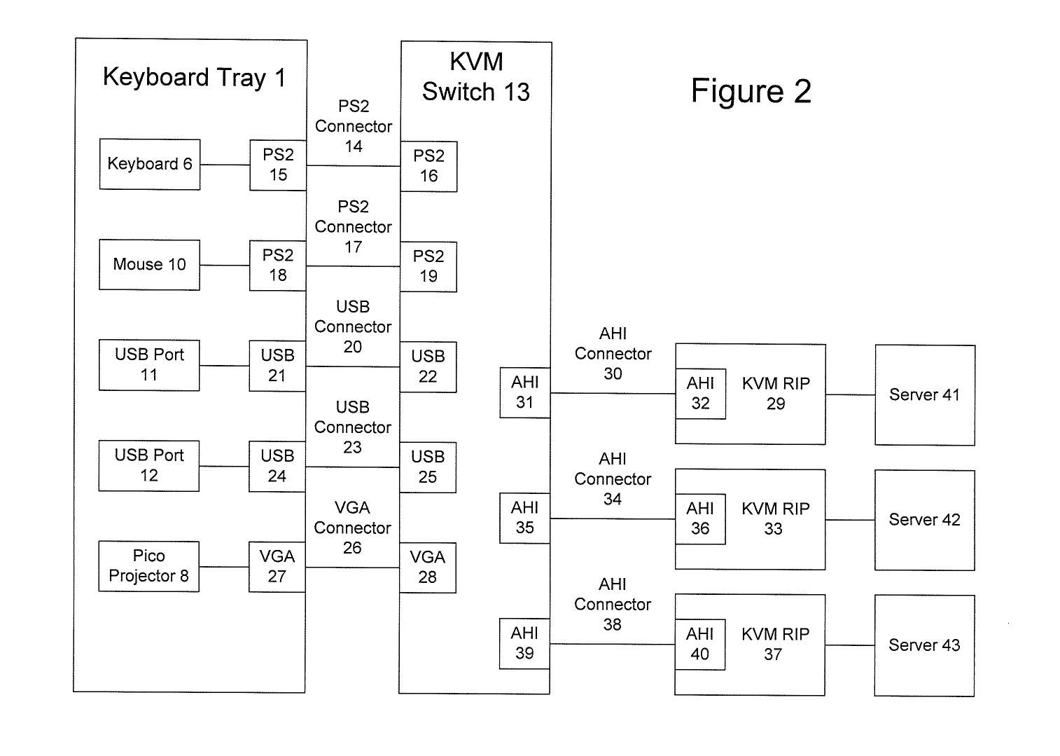

FIG. 2 illustrates a block diagram of a keyboard tray and its electronic connections to a plurality of servers through a KVM switch and a plurality of KVM RIP devices, made in accordance with methods and systems consistent with the present invention. Keyboard tray 1 comprises keyboard 6, mouse 10, media 11, media 12, and projector 8. Keyboard 6 is connected and sends electronic data signals to KVM switch 13 by PS/2 connector 14, which is inserted into PS/2 connection port 15 on keyboard tray 1 and PS/2 connection port 16 on KVM switch 13. Mouse 10 is connected and sends data signals to KVM switch 13 by PS/2 connector 17, which is inserted into PS/2 connection port 18 on keyboard tray 1, and PS/2 connection port 19 on KVM switch 13. Media 11 is connected and sends data signals to KVM switch 13 by USB connector 20, which is inserted into USB connection port 21 on keyboard tray 1, and USB connection port 22 on KVM switch 13. Media 12 is connected and sends data signals to KVM switch 13 by USB connector 23, which is inserted into USB connection port 24 on keyboard tray 1, and USB connection port 25 on KVM switch 13. Media 11 and 12 may be any suitable device or media such as a USB drive, CD, DVD, etc. Projector 8 is connected and sends data signals to KVM switch 13 by VGA connector 26, which is inserted into VGA connection port 27 on keyboard tray 1, and VGA connection port 28 on KVM switch 13. Electronic signals from keyboard tray 1 which reach KVM switch 13 may then be routed to server 41, server 42, or server 43. From KVM switch 13, electronic signals are routed through either AHI (Avocent Highspeed Interface) connector 30, AHI connector 34, or AHI connector 38. KVM switch 13 is connected and sends data signals to KVM RIP 29 by ATE connector 30, which is inserted into AHI connection port 31 on KVM switch 13, and AHI connection port 32 on KVM RIP 19. Although the Avocent Highspeed Interface protocol (from Avocent Corp.) is disclosed, any other suitable protocol may be used.

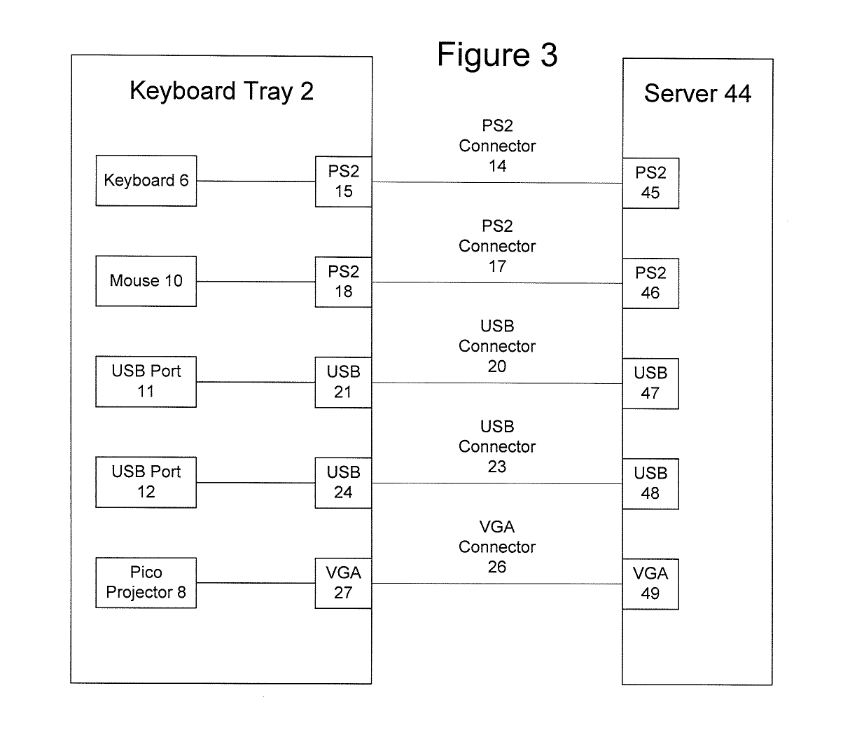

FIG. 3 illustrates a block diagram of a keyboard tray and its electronic connections to a server, made in accordance with methods and systems consistent with the present invention. Keyboard 6 on keyboard tray 1 is connected and sends electronic data signals to server 44 by PS/2 connector 14, which is inserted into PS/2 connection port 15 on keyboard tray 1 and PS/2 connection port 45 on server 44. Mouse 10 is connected and sends data signals to server 44 by PS/2 connector 17, which is inserted into PS/2 connection port 18 on keyboard tray 1, and PS/2 connection port 46 on server 44. Media 11 is connected and sends data signals to server 44 by USB connector 20, which is inserted into USB connection port 21 on keyboard tray 1, and USB connection port 47 on server 44. Media 12 is connected and sends data signals to server 44 by USB connector 23, which is inserted into USB connection port 24 on keyboard tray 1, and USB connection port 48 on server 44. Projector 8 is connected and sends data signals to server 44 by VGA connector 26, which is inserted into VGA connection port 27 on keyboard tray 1, and VGA connection port 49 on server 44.

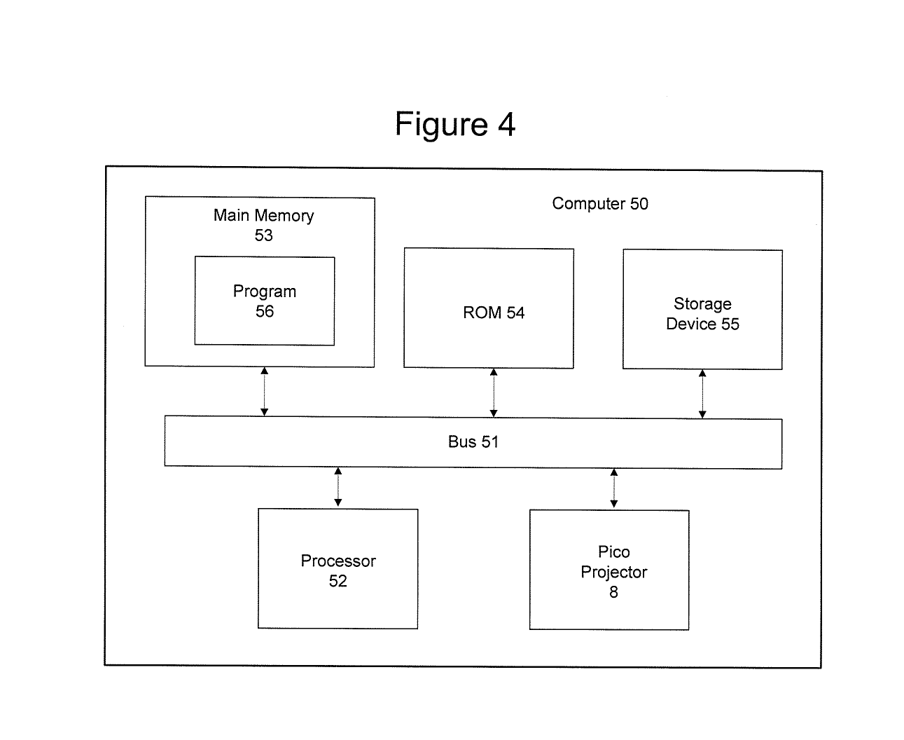

FIG. 4 illustrates an exemplary computer system consistent with systems and methods consistent with the present invention. Computer 50 may be a keyboard tray, laptop computer or other portable computer, or any other suitable computer system. Computer 50 includes a bus 51 or other communication mechanism for communicating information, and a processor 52 coupled with bus 51 for processing the information. Computer 50 also includes pico projector 8, which may be a laser-based projector, high brightness based LED projector, LCD based projector, LCoS based projector, or any other suitable projector. Pico projector 8 may be connected to bus 51 and may be directed to display images by processor 52 or other video card component. Computer 50 also includes a main memory 53, such as a random access memory (RAM) or other dynamic storage device, coupled to bus 51 for storing information and instructions to be executed by processor 52. In addition, main memory 53 may be used for storing temporary variables or other intermediate information during execution of instructions to be executed by processor 52. Main memory 53 includes a program 56 for implementing processing consistent with methods and systems in accordance with the present invention. Computer 50 further includes a Read-Only Memory (ROM) 54 or other static storage device coupled to bus 51 for storing static information and instructions for processor 52. A storage device 55, such as a magnetic disk or optical disk, is provided and coupled to bus 51 for storing information and instructions.

According to one embodiment, processor 52 executes one or more sequences of one or more instructions contained in main memory 53. Such instructions may be read into main memory 53 from another computer-readable medium, such as storage device 55. Execution of the sequences of instructions in main memory 53 causes processor 52 to perform processes described herein. One or more processors in a multi-processing arrangement may also be employed to execute the sequences of instructions contained in main memory 53. In alternative embodiments, hard-wired circuitry may be used in place of or in combination with software instructions. Thus, embodiments are not limited to any specific combination of hardware circuitry and software.

Although described relative to main memory 53 and storage device 55, instructions and other aspects of methods and systems consistent with the present invention may reside on another computer-readable medium, such as a floppy disk, a flexible disk, hard disk, magnetic tape, a CD-ROM, magnetic, optical or physical medium, a RAM, a PROM, and EPROM, a FLASH-EPROM, any other memory chip or cartridge, or any other medium from which a computer can read, either now known or later discovered.

The foregoing description of various embodiments provides illustration and description, but is not intended to be exhaustive or to limit the invention to the precise form disclosed. Modifications and variations are possible in light of the above teachings or may be acquired from practice in accordance with the present invention. It is to be understood that the invention is intended to cover various modifications and equivalent arrangements included within the spirit and scope of the appended claims.

What is claimed is:

1. A KVM keyboard tray, comprising:
a keyboard; and
a display comprising:
a projector configured to project an image onto a screen; and
the screen configured to receive the projected image from the projector.

2. The KVM keyboard tray of claim 1, wherein the keyboard is connected to the screen.

3. The KVM keyboard tray of claim 1, wherein the projector is connected to the keyboard.

4. The KVM keyboard tray of claim 1, wherein the projector is an LED projector.

5. The KVM keyboard tray of claim 1, wherein the projector is an LCOS projector.

6. The KVM keyboard tray of claim 1, wherein the projector is an LCD projector.

7. The KVM keyboard tray of claim 1, wherein the screen is plastic.

8. The KVM keyboard tray of claim 1, wherein the screen does not generate images.

9. The KVM keyboard tray of claim 1, wherein an angle of the screen with respect to the projector is adjustable.

10. The KVM keyboard tray of claim 1, wherein the screen is hinged.

11. The KVM keyboard tray of claim 1, wherein the screen is retractable.

12. A portable computer, comprising:
a keyboard;
a processor; and
a display comprising:
a projector configured to project an image onto a screen; and
the screen configured to receive the projected image from the projector.

13. The portable computer of claim 12, wherein the keyboard is connected to the screen.

14. The portable computer of claim 12, wherein the projector is connected to the keyboard.

15. The portable computer of claim 12, wherein the portable computer is a laptop computer.

16. The portable computer of claim 12, wherein the projector is an LED projector.

17. The portable computer of claim 12, wherein the projector is an LCOS projector.

18. The portable computer of claim 12, wherein the projector is an LCD projector.

19. The portable computer of claim 12, wherein the screen is plastic.

20. The portable computer of claim 12, wherein the screen does not generate images.

21. The portable computer of claim 12, wherein an angle of the screen with respect to the projector is adjustable.

22. The portable computer of claim 12, wherein the screen is hinged.

23. The portable computer of claim 12, wherein the screen is retractable.
